(19) United States
(12) Patent Application Publication
(10) Pub. No.: US 2024/0418743 A1
(43) Pub. Date: Dec. 19, 2024

(54) THREE SEISMIC MASS Z-AXIS ACCELEROMETER AND MANUFACTURING METHOD THEROF

(71) Applicant: MiraMEMS Sensing Technology Co., Ltd, SUZHOU INDUSTRIAL PARK (CN)

(72) Inventor: Li-Tien TSENG, SUZHOU (CN)

(21) Appl. No.: 18/751,652

(22) Filed: Jun. 24, 2024

(30) Foreign Application Priority Data
Jun. 16, 2023 (CN) 202310760204.4

(51) Int. Cl. G01P 15/125; B81B 3/00; G01P 15/08

(52) U.S. Cl. CPC G01P 15/125; B81B 3/0051; G01P 15/0802; B81B 2201/0235; G01P 2015/0831

(57) ABSTRACT

A three seismic mass Z-axis accelerometer includes a CMOS substrate, a MEMS substrate and a cap substrate which are arranged parallel to each other and bonded to each other. The MEMS substrate includes a connection seismic mass deposited between two seesaw seismic masses and connected to the seesaw masses through connecting springs. The connection seismic mass and seesaw seismic masses are respectively corresponding to sensing electrode plates on the CMOS substrate to form a plurality of capacitor structures. The CMOS substrate further includes a plurality of electric-connection anchor structures which are respectively mounted to and electrically connected with the COMS substrate and the cap substrate, and a plurality of cap anchor structures respectively connected with the cap substrate.

### CROSS REFERENCES

This Application claims benefit of CN Patent Application No. 2023107602044 filed on 2023 Jun. 26 and titled as “Z-Axis Three Seismic Mass Accelerometer and Manufacturing Method Therefor”, the disclosure of which is hereby incorporated by references.

### 1. FIELD OF THE INVENTION

The present invention relates to a MEMS technology for detecting acceleration, particularly to a Z-axis accelerometer for detecting the gravitational acceleration direction.

### 2. DESCRIPTION OF THE PRIOR ART

A micro electro mechanical system (MEMS) is referred to an electromechanical system having a combination of electronic and mechanical functions and able to detect a minor change of a physical property fast and accurately. For an example of MEMS-based Z-axis accelerometers, a Taiwan patent of publication No. I762816 disclosed a Z-axis seesaw accelerometer with a mobile structure embedded thereinside, wherein the mobile structure can move pivotally or translate to leave the plane of the seesaw beam to enhance the sensitivity. For another example of MEMS-based Z-axis accelerometers, a Taiwan patent of publication No. I716999 disclosed a design having pivotal rods suspended above a substrate, wherein the pivotal rods are separated from the substrate by different distances to enhance the sensitivity.

### SUMMARY OF THE INVENTION

The present invention provides a three seismic mass Z-axis accelerometer and a manufacturing method thereof, wherein the MEMS structure has two types of anchor structures respectively functioning as fixing structures and electric-conduction structures, whereby to exempt the fixing structures from being damaged by the bonding pressure during the fabrication process.

The present invention provides a three seismic mass Z-axis accelerometer and a manufacturing method thereof, wherein the MEMS structure has a connection seismic mass and two seesaw seismic masses at two sides to enable the measurement of the acceleration in the Z-axis direction.

The present invention provides a three seismic mass Z-axis accelerometer and a manufacturing method thereof, wherein the MEMS structure has buckling compensation capacitor structures, whereby to reduce the influence of the stresses caused by some factors, such as the fabrication process.

A three seismic mass Z-axis accelerometer comprises a complementary metal oxide semiconductor (CMOS) substrate, a micro electro mechanical system (MEMS) substrate, and a cap substrate, which are arranged parallel to each other and bonded to each other. The three seismic mass Z-axis accelerometer of the present invention has characteristics: the MEMS substrate includes two seesaw seismic masses; a connection seismic mass is arranged between two seesaw seismic masses and respectively connected with two seesaw seismic masses through a plurality of connecting springs; and perforated areas are formed between the connection seismic mass and two seesaw seismic masses. The three seismic mass Z-axis accelerometer of the present invention also has a characteristic: the connection seismic mass and two seesaw seismic masses are respectively corresponding to a plurality of sensing electrode plates on the CMOS substrate to form a plurality of capacitor structures. The three seismic mass Z-axis accelerometer of the present invention also has characteristics: a plurality of electric-connection anchor structures is respectively fixed to and electrically connected with the CMOS substrate and the cap substrate; each of the electric-connection anchor structures is corresponding to a first cap pillar of the cap substrate and a bonding pad of the CMOS substrate; a plurality of cap anchor structures is respectively fixed to the cap substrate; each of the cap anchor structures is corresponding to and fixed to a second cap pillar; the plurality of electric-connection anchor structures and the plurality of the cap anchor structures are arranged in the perforated areas.

In some embodiments, the MEMS substrate further comprises a plurality of bow-shape compensation capacitor structures, which are arranged around the connection seismic mass and the seesaw seismic masses.

A manufacturing method of the abovementioned three seismic mass Z-axis accelerometer comprises steps: providing a cap substrate including a plurality of first cap pillars and a plurality of second cap pillars; fusing a primitive substrate to the cap substrate; patterning the primitive substrate to form an MEMS substrate; providing a CMOS substrate including a plurality of bonding pads and a plurality of sensing electrode plates; joining the MEMS substrate and the CMOS substrate in an eutectic method.

### BRIEF DESCRIPTION OF THE DRAWINGS

FIG. 1 is a side view schematically showing a three seismic mass Z-axis accelerometer according to a first embodiment of the present invention.

FIG. 2 is a front view schematically showing a MEMS substrate of a three seismic mass Z-axis accelerometer according to the first embodiment of the present invention.

FIG. 3 is a side view schematically showing a portion of a MEMS sensing structure of a three seismic mass Z-axis accelerometer according to one embodiment of the present invention.

FIG. 4 is a side view schematically showing a portion of a MEMS sensing structure of a three seismic mass Z-axis accelerometer according to one embodiment of the present invention.

FIG. 5 is a side view schematically showing a portion of a MEMS sensing structure of a three seismic mass Z-axis accelerometer according to one embodiment of the present invention.

FIG. 6 is a front view schematically showing a MEMS substrate of a three seismic mass Z-axis accelerometer according to a second embodiment of the present invention.

FIG. 7 is a sectional view taken along Line BB′ in FIG. 6.

FIG. 8 is a front view schematically showing compensation capacitor structures of a MEMS substrate of a three seismic mass Z-axis accelerometer according to the second embodiment of the present invention.

FIG. 9 is a front view schematically showing a layout of a three-mass sensing structure and compensation capacitor structures of a MEMS substrate structure of a three seismic mass Z-axis accelerometer according to one embodiment of the present invention.

FIG. 10 is a front view schematically showing a layout of a three-mass sensing structure and compensation capacitor structures of a MEMS substrate structure of a three seismic mass Z-axis accelerometer according to another embodiment of the present invention.

FIG. 11 is a front view schematically showing a layout of a three-mass sensing structure and compensation capacitor structures of a MEMS substrate structure of a three seismic mass Z-axis accelerometer according to yet another embodiment of the present invention.

FIG. 12 is a front view schematically showing a layout of a three-mass sensing structure and compensation capacitor structures of a MEMS substrate structure of a three seismic mass Z-axis accelerometer according to a further embodiment of the present invention.

FIG. 13 is a front view schematically showing buckling compensation capacitor structures of a MEMS substrate structure of a three seismic mass Z-axis accelerometer according to one embodiment of the present invention.

FIG. 14 is a front view schematically showing buckling compensation capacitor structures of a MEMS substrate structure of a three seismic mass Z-axis accelerometer according to another embodiment of the present invention.

FIG. 15 is a front view schematically showing a non-compensation capacitor pair structure of a MEMS substrate structure of a three seismic mass Z-axis accelerometer according to one embodiment of the present invention.

FIG. 16 is a front view schematically showing a non-compensation capacitor pair structure of a MEMS substrate structure of a three seismic mass Z-axis accelerometer according to another embodiment of the present invention.

FIG. 17 is a front view schematically showing a non-compensation capacitor pair structure of a MEMS substrate structure of a three seismic mass Z-axis accelerometer according to yet another embodiment of the present invention.

FIG. 18 is a sectional view schematically showing a portion of structures in a manufacturing process of a three seismic mass Z-axis accelerometer according to one embodiment of the present invention.

FIG. 19 is a sectional view schematically showing a portion of structures in a manufacturing process of a three seismic mass Z-axis accelerometer according to one embodiment of the present invention.

FIG. 20 is a sectional view schematically showing a portion of structures in a manufacturing process of a three seismic mass Z-axis accelerometer according to one embodiment of the present invention.

FIG. 21 is a sectional view schematically showing a portion of structures in a manufacturing process of a three seismic mass Z-axis accelerometer according to one embodiment of the present invention.

FIG. 22 is a sectional view schematically showing a portion of structures in a manufacturing process of a three seismic mass Z-axis accelerometer according to one embodiment of the present invention.

FIG. 23 is a sectional view schematically showing a portion of structures in a manufacturing process of a three seismic mass Z-axis accelerometer according to one embodiment of the present invention.

FIG. 24 is a sectional view schematically showing a portion of structures in a manufacturing process of a three seismic mass Z-axis accelerometer according to one embodiment of the present invention.

FIG. 25 is a sectional view schematically showing a portion of structures in a manufacturing process of a three seismic mass Z-axis accelerometer according to one embodiment of the present invention.

FIG. 26 is a sectional view schematically showing a portion of structures in a manufacturing process of a three seismic mass Z-axis accelerometer according to one embodiment of the present invention.

FIG. 27 is a sectional view schematically showing a portion of structures in a manufacturing process of a three seismic mass Z-axis accelerometer according to one embodiment of the present invention.

### DESCRIPTION OF THE PREFERRED EMBODIMENT

The embodiments described below are only for exemplification. Although the descriptions are involved in one or more embodiments thereinafter, it does not mean that the characteristics are only applicable to a single embodiment. The characteristics of different embodiments may be combined and applied to other embodiments. The characteristics of different embodiments may be combined and applied to other embodiments. Below, the devices able to implement various embodiments will be introduced, and the elements thereof are also described in detail, whereby to demonstrate the characteristics of the present invention. However, the elements of the existing accelerometers, which have been familiar to the persons skilled in the art, are not necessarily described in the specification.

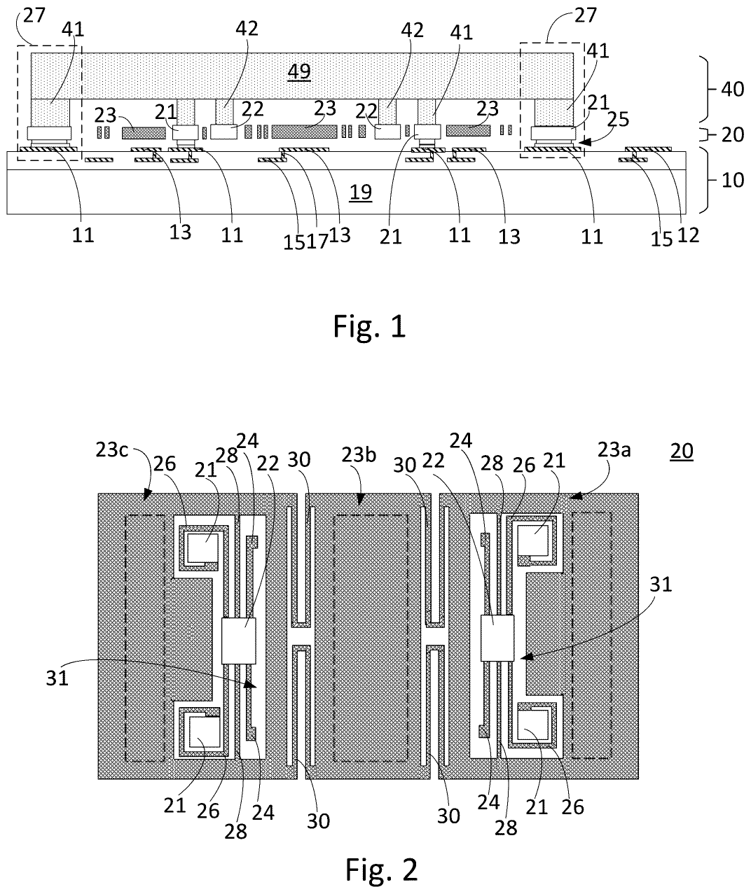

Refer to FIG. 1. FIG. 1 is a side view schematically showing a three seismic mass Z-axis accelerometer according to a first embodiment of the present invention. The three seismic mass Z-axis accelerometer includes a CMOS substrate 10, a MEMS substrate 20, and a cap substrate 40, and these substrates are arranged parallel to each another and bonded to each another. The MEMS substrate 20 is arranged between the CMOS substrate 10 and the cap substrate 40. The CMOS substrate 10 may include a CMOS body 19 and a CMOS circuit structure arranged on the surface of the CMOS body 19. The CMOS circuit structure includes a plurality of electric-conduction structures, such as electric-conduction pads and electric-conduction holes for electric connection, electric conduction, or mechanical connection. In one embodiment, the CMOS circuit structure includes one or more bonding pads 11, one or more solder pads 12, one or more sensing electrode plates 13, and a plurality of electric-conduction holes 17. The bonding pads 11 physically contact the MEMS substrate 20 and the cap substrate 40 and are electrically connect with the MEMS substrate 20, wherein the MEMS substrate 20 and the cap substrate 40 have been joined together in a fusion method. The solder pads 12 are exposed on the surface of the CMOS substrate 10 and used for connection with other structures. The sensing electrode plates 13 are corresponding to the MEMS substrate 20. The plurality of electric-conduction holes 17 respectively contacts and is electrically connected with electric-conduction wires 15 and the bonding pad 11, the solder pads 12, and the sensing electrode plates 13. The cap substrate 40 may include a cap body 49 and some cap pillars protruding from the cap body 49 and facing the MEMS substrate 20. In one embodiment, one or more first cap pillars 41 are corresponding to the bonding pads 11 of the CMOS substrate 10 and connected with the bonding pads 11 through the MEMS substrate 20; second cap pillars 42 and the MEMS substrate 20 are bonded to each other. The MEMS substrate 20 includes a plurality of seismic masses 23 of the MEMS sensing structure, a plurality of cap anchor structures 22, a plurality of electric-connection anchor structure 21, and a plurality of bonding structures 25. The MEMS substrate 20 may be regarded as one with a mobile sensing structure. The cap anchor structures 22 are connected with the overall mobile sensing structure to secure the overall mobile sensing structure through sensing springs (will be described below). The cap anchor structures 22 are also connected with the second cap pillars 42. The electric-connection anchor structures 21 are connected with the first cap pillars 41 of the cap substrate 40. Through the bonding structures 25, the electric-connection anchor structures 21 contact the bonding pads 11 of the CMOS substrate 10 and are electrically connected with the bonding pads 11 of the CMOS substrate 10 for electric conduction and security. To speak it in detail, the first cap pillars 41, which are arranged along the perimeter of the cap substrate 40, surround the sensing structure of the MEMS substrate 20 to form an annular structure and cooperate with the bonding pads 11 of the CMOS substrate 10, which is disposed under, to form an airtight bond ring 27 (the areas encircled by the dot lines in FIG. 1). Therefore, the MEMS sensing structure operates in an airtight environment.

FIG. 2 is a front view schematically showing a first embodiment of a MEMS substrate of the three seismic mass Z-axis accelerometer of the present invention. Refer to FIG. 1 and FIG. 2 simultaneously. The seismic masses 23 of the MEMS sensing structure includes a first seismic mass 23c, a second seismic mass 23b and a third seismic mass 23a. The areas encircled by the dot lines in FIG. 2 indicate the regions where the sensing electrode plates 13 of the MEMS substrate 10 are disposed. The first seismic mass 23c, the second seismic mass 23b and the third seismic mass 23a are respectively corresponding to the sensing electrode plates 13 of the MEMS substrate 10 to form capacitor structures. The second seismic mass 23b is arranged between the first seismic mass 23c and the third seismic mass 23a and respectively joined to the first seismic mass 23c and the third seismic mass 23a through connecting springs 30. The first seismic mass 23c and the third seismic mass 23a are termed the seesaw seismic masses, and the second seismic mass 23b is termed the connection seismic mass. The cap anchor structures 22 and the electric-connection anchor structures 21 are disposed in perforated regions 31 among the connecting springs 30, the first seismic mass 23c and the third seismic mass 23a. Each cap anchor structure 22 is connected with the overall mobile sensing structure (the MEMS substrate 20) through one or more sensing springs 28. In other words, each cap anchor structure 22 is connected with the seesaw seismic mass through the sensing springs 28 and includes one or more stop springs 24 extended to the perforated area 31. An electric-conduction spring 26 electrically connects with the electric-connection anchor structures 21 and the cap anchor structures 22, whereby the electric-connection anchor structures 21 and the cap anchor structures 22 are electrically connected. The electric-connection anchor structure 21 is electrically connected with the bonding pads 11 of the CMOS substrate 10 that is disposed underneath the electric-connection anchor structure 21, through the bonding structure 25 below the electric-connection anchor structure 21.

According aforementioned, there are two types of anchor structures: the electric-connection anchor structures 21 and the cap anchor structures 22 in the MEMS sensing structure, which respectively function as the electric-conduction structures and the fixing structures. Thus, on one hand, in the bonding process, the suspended cap anchor structures 22 will not be damaged by the bonding pressure, and the risk of cracking the cap anchor structures 22 is reduced. On the other hand, if the electric-connection anchor structures 21 are cracked by the bonding pressure, the electric connection still exists, and the stability of the sensing structure would not be affected. Therefore, the design of the present invention can improve product stability and fabrication yield.

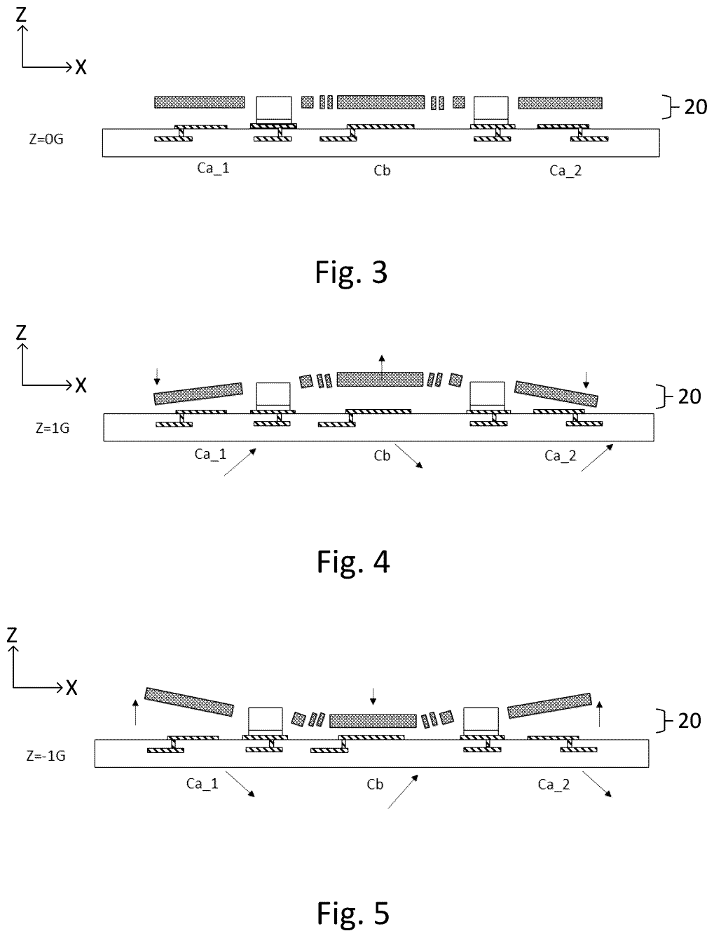

FIGS. 3-5 are side views schematically showing portions of the MEMS sensing structure of a three seismic mass Z-axis accelerometer according to one embodiment of the present invention. FIG. 3 shows that no force is applied along the Z axis. FIG. 4 shows that an acceleration in +Z direction (gravity force of acceleration) is applied along the Z axis. FIG. 5 shows that an acceleration in −Z direction is applied along the Z axis. In order to explain conveniently, a portion of structure is omitted. Capacitor symbols Ca_1, Ca_2 and Cb are labelled below the circuit structure of the CMOS substrate; the direction of each seismic mass' displacement due to net moment generated by unbalanced see-saw structure under Z acceleration is indicated by single solid-line arrows appearing above the MEMS substrate 20; the single sloid-line arrows beside the capacitor symbols indicate the directions of the change of the capacitance. Refer to FIGS. 1-5 simultaneously. The capacitor formed by the first seismic mass 23c and the sensing electrode plate 13 is expressed by “Cal”; the capacitor formed by the second seismic mass 23b and the sensing electrode plate 13 is expressed by “Cb”; the capacitor formed by the third seismic mass 23a and the sensing electrode plate 13 is expressed by “Ca_2”. While the MEMS sensing structure does not experience any acceleration along the Z axis, Cb is the sum of Ca_1 and Ca_2, and the capacitance variation delta C ((AC)=Ca_1+Ca_2−Cb) is zero. While the MEMS sensing structure expresses an inertial motion response to a gravitational acceleration or an external acceleration, the sensing springs 28 of the MEMS sensing structure are twisted to form a seesaw motion. The dual-seesaw structure formed by three seismic masses operates to generate an arch-bridge motion (buckling motion). Thus, the seismic masses at two sides generate seesaw-like tilting motions, and the mass at the center generates up-and-down motions and keeps parallel to the MEMS sensing structure. The motion direction of the seismic masses at two sides is opposite to the motion direction of the mass at the center. The capacitance variation of the seismic masses at two sides and the sensing electrode plates 13 of the CMOS substrate is also opposite to that of the mass at the center and the sensing electrode plate 13. Thus, both form a differential capacitor pair. The differential capacitor pair of the present invention may cooperate with an ASIC sensing circuit (not shown in the drawings) to form a differential sensing circuit to measure capacitance variation. Refer to FIG. 1 and FIG. 4. While the MEMS sensing structure responses to 1G gravitational acceleration or external acceleration along the Z axis, the plate of the second seismic mass 23b moves upward along the positive Z axis, and the plates of the first seismic mass 23c and the third seismic mass 23a act downward incliningly. The regions of the first seismic mass 23c and the third seismic mass 23a, which are far away from the second seismic mass 23b, are respectively closer to the sensing electrode plate 13. In this situation, the capacitance Ca_1 and the capacitance Ca_2 increase, and the capacitance Cb decreases. Thus, delta C (AC) is greater than zero. Refer to FIG. 1 and FIG. 5. While the MEMS sensing structure responses to −1G gravitational acceleration or external acceleration along the Z axis, the plate of the second seismic mass 23b moves downward along the positive Z axis, and the plates of the first seismic mass 23c and the third seismic mass 23a act upward incliningly. The regions of the first seismic mass 23c and the third seismic mass 23a, which are far away from the second seismic mass 23b, are respectively farer from the sensing electrode plate 13. In this situation, the capacitance Ca_1 and the capacitance Ca_2 decrease, and the capacitance Cb increases. Thus, delta C (AC) is smaller than zero. It is observed in the side views: while the sensing structure expresses an inertial motion in response to a gravitational or external acceleration, the seismic masses Ca_1, Ca_2 and Cb are displaced to form an arch-bridge (buckling) shape. The direction of the deformation of the arch-bridge shape may be reversed because of different arrangement of the balance weights of the seismic masses. FIG. 4 and FIG. 5 are only to exemplify the present invention but not to limit the present invention.

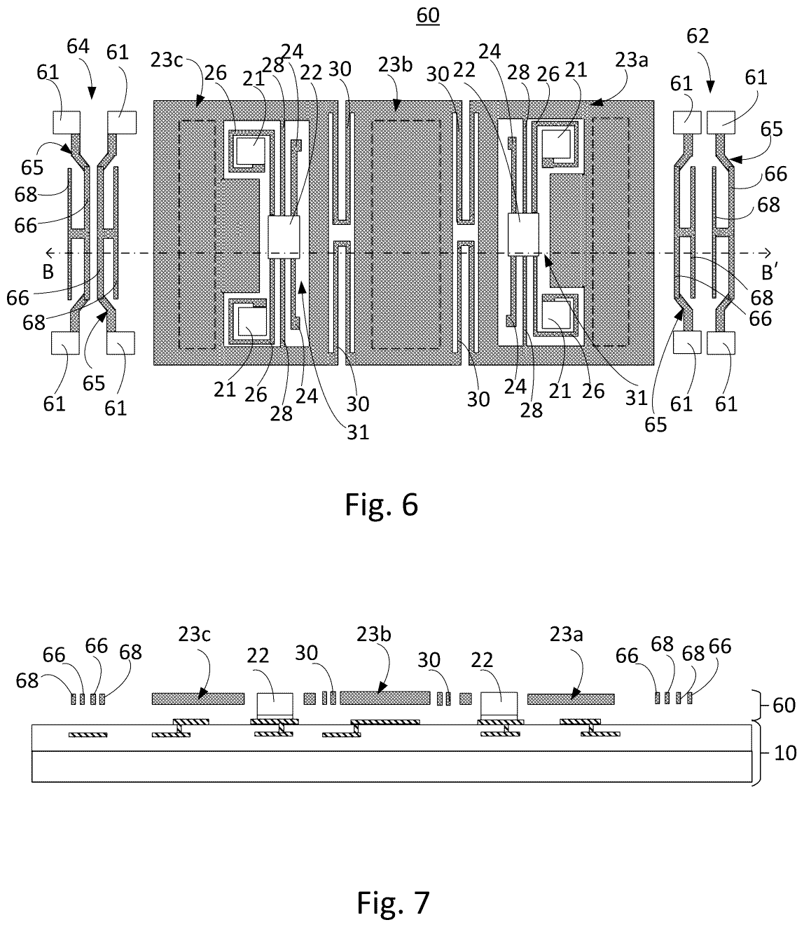

FIG. 6 is a front view schematically showing an MEMS substrate of a three seismic mass Z-axis accelerometer according to a second embodiment of the present invention. FIG. 7 is a sectional view taken along Line BB′ in FIG. 6. Refer to FIG. 1, FIG. 2, FIG. 6 and FIG. 7. In addition to the MEMS mobile sensing structure shown in FIG. 2, there are bow-shape compensation capacitor structures arranged around the first seismic mass 23c and the third seismic mass 23a in the MEMS substrate 60, such as a first bow-shape compensation capacitor structure 64 and a second bow-shape compensation capacitor structure 62 are respectively arranged on two sides of the MEMS mobile sensing structure. The first bow-shape compensation capacitor structure 64 and the second bow-shape compensation capacitor structure 62 are also disposed inside the airtight chamber formed by the airtight bond ring 27, the cap substrate 40 and the CMOS substrate 10 (as shown in FIG. 1). Each of the first bow-shape compensation capacitor structure 64 and the second bow-shape compensation capacitor structure 62 includes two bow-shape structures arranged symmetrically with four anchor structures 61 arranged opposite to each other. A first capacitor plate 66 connects to two opposite anchor structures 61 through two turning structures 65 respectively, and a second capacitor plate 68 arranged opposite to the first capacitor plate 66 connects with the first capacitor plate 66 at the middle position. For convenient description, the first capacitor plate 66, which is connected with the turning structure 65, is adopted for illustration. The first bow-shape compensation capacitor structure 64 may be regarded as a face-to-face type considering the first capacitor plates 66 neighbor each other. The second bow-shape compensation capacitor structure 62 may be regarded as a back-to-back type because the second capacitor plates 68 are arranged between the first capacitor plates 66. In general, stress may induce the deformation of the MEMS sensing structure and even make the displacement of the 0G level bias. The sources of stress include residual stress of package, residual stress of workpiece welding, assembly stress, ambient temperature change. While external stress induce deformation of a chip, the gap between the sensing structure and the sensing electrode plate will change. Thus, the capacitance also changes. The compensation capacitors may be used to decrease the offset level due to abovementioned stress-induced deformation. Besides, the turning structure 65, such as a buckling structure, may amplify deformation and increase compensation range.

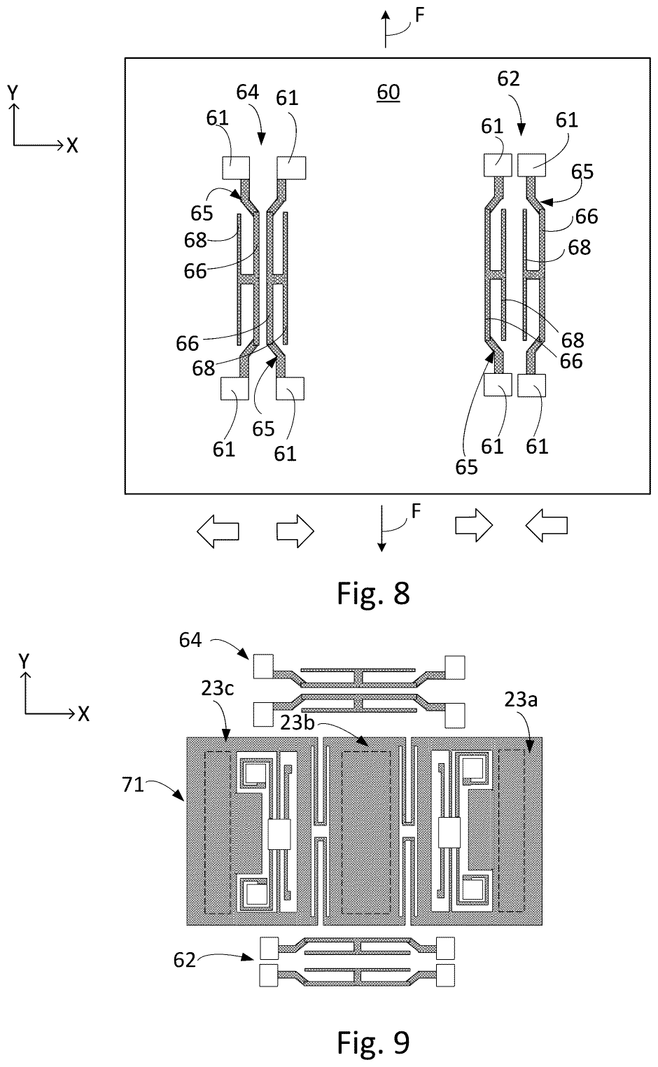

FIG. 8 is a front view schematically showing compensation capacitor structures of a MEMS substrate of a three seismic mass Z-axis accelerometer according to the second embodiment of the present invention. Refer to FIG. 1, FIG. 2, FIG. 6, FIG. 7, and FIG. 8. The bow-shape capacitor structure of each pair of the first capacitor plate 66 and the second capacitor plate 68 is joined to the MEMS substrate 60 via the anchor structures 61 arranged at two ends of the major axis (long axis). As the bow-shape capacitor structure has no seismic mass, gravitational force would not induce the bow-shape capacitor structure to deform. However, the bow-shape capacitor structure may be deformed by the stress between the anchor structures 61 arranged at two ends. If the MEMS substrate 60 experiences the tensile stress F along the Y axis, the first bow-shape compensation capacitor structure 64 (the face-to-face type) will have a tensile deformation in the X-axis direction, as shown by the arrows below the MEMS substrate 60. Therefore, the Y-axis direction tensile stress pulls the first bow-shape compensation capacitor structure 64 and then increases the spacing between the two buckling plates, which results in decreasing a first compensation capacitance “Comp Ca” of the first bow-shape compensation capacitor structure 64. On the other hand, the second bow-shape compensation capacitor structure 62 (the back-to-back type) will have a compressive deformation in the X-axis direction, as shown by the arrows below the MEMS substrate 60. Therefore, the Y-axis direction tensile stress decreases the spacing between the two buckling plates of the second bow-shape compensation capacitor structure 62, which results in increasing a second compensation capacitance “Comp Cb” of the second bow-shape compensation capacitor structure 62. It is easily understood: if the MEMS substrate 60 experiences the compressive stress along the Y axis, two first capacitor plates 66 (the buckling capacitor plates) of the first bow-shape compensation capacitor structure 64 (the face-to-face type) will respectively have compressive buckling deformations in the X-axis direction. Owing to the face-to-face type arrangement, the spacing between the first capacitor plates 66 is decreased and the first compensation capacitance “Comp Ca” of the first bow-shape compensation capacitor structure 64 increases. On the other hand, two first capacitor plates 66 (the buckling capacitor plates) of the second bow-shape compensation capacitor structure 62 (the back-to-back type) will respectively have tensile deformations in the X-axis direction. Owing to the back-to-back type arrangement, the spacing between the first capacitor plates 66 is increased and the second compensation capacitance “Comp Cb” of the second bow-shape compensation capacitor structure 62 decreases. For the bow-shape compensation capacitor structure, two buckling structures, which are arranged in left-right symmetry, may form two types of capacitor pairs. If a pair of capacitors are simultaneously deformed toward the symmetric axis, it is defined as a forward compensation capacitor pair, wherein the capacitor plates become closer to each other, and the capacitance increases, such as the face-to-face type first bow-shape compensation capacitor structure 64. If a pair of capacitors are simultaneously deformed far away from the symmetric axis, it is defined as a backward compensation capacitor pair, such as the back-to-back type second bow-shape compensation capacitor structure 62. Therefore, the present invention can eliminate the 0G level displacement, which is induced by various stresses, via adding bow-shape compensation capacitor structures (including the face-to-face type and the back-to-back type) to the MEMS substrate. The arrangement of the bow-shape compensation capacitor structures is exemplified in FIG. 6, wherein the major axis of the first bow-shape compensation capacitor structure 64 is essentially parallel to the major axis of the second bow-shape compensation capacitor structure 62; the major axis of the first bow-shape compensation capacitor structure 64 is also essentially parallel to the long axes of the first seismic mass 23c, the second seismic mass 23b and the third seismic mass 23a.

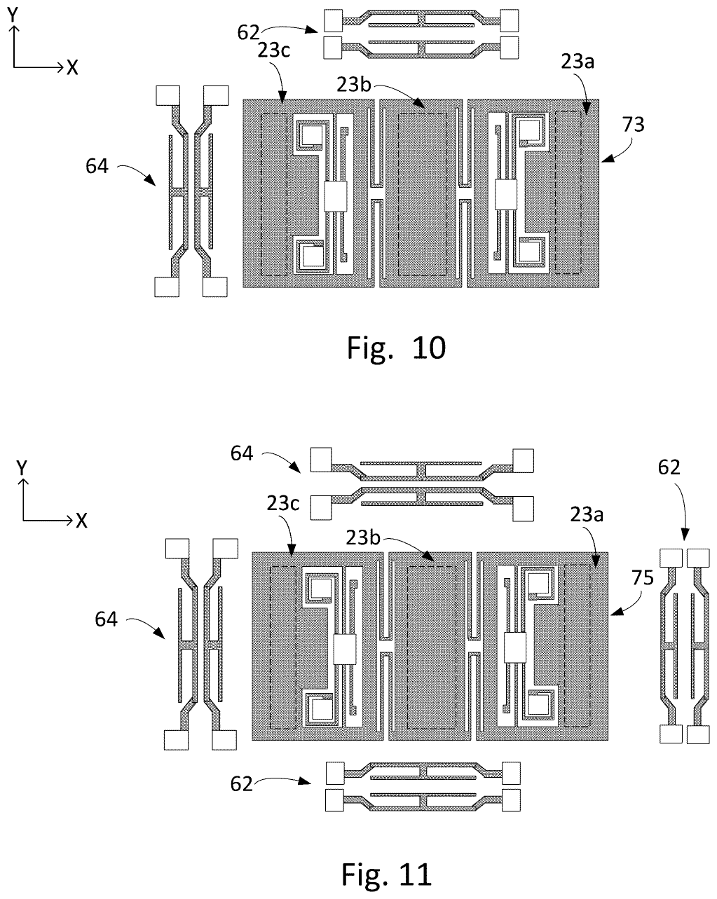

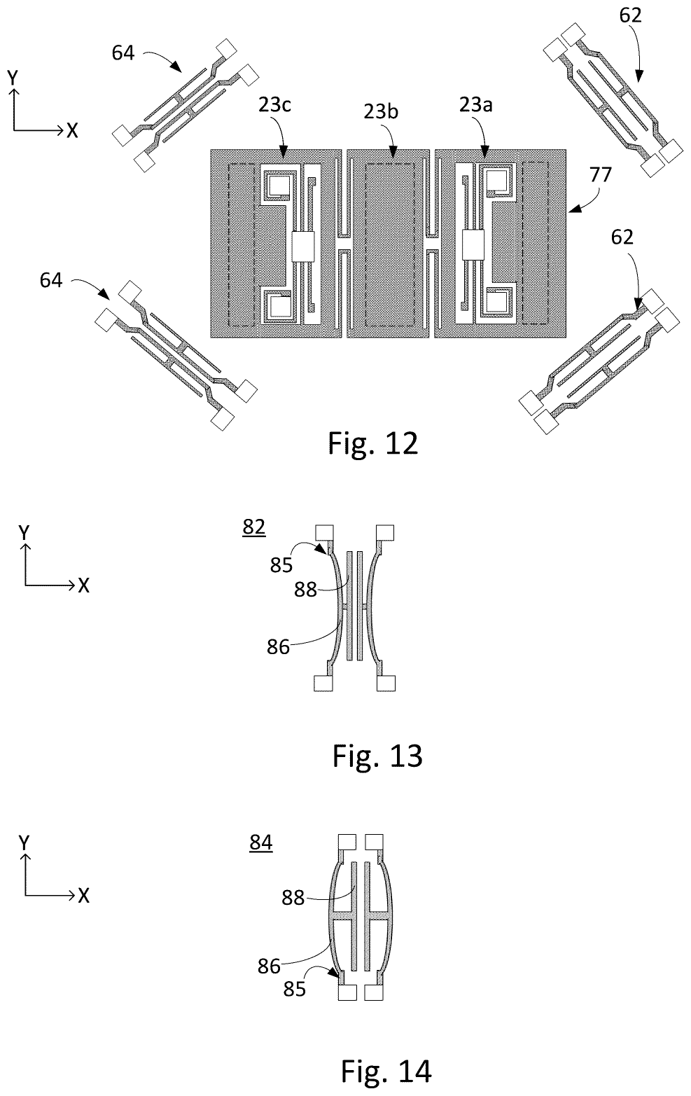

FIGS. 9-12 are front views schematically showing the three seismic mass sensing structure and the compensation capacitor structures of the MEMS substrate structure of a three seismic mass Z-axis accelerometer according to one embodiment of the present invention. For convenient description, only the three seismic mass sensing structure and the compensation capacitor structures of the MEMS substrate structure are shown in the drawings, and the other portions may be omitted. Refer to FIG. 9. The three seismic mass sensing structure 71 includes a first seismic mass 23c, a second seismic mass 23b, a third seismic mass 23a and the COM substrate arranged therebelow jointly to form the MEMS sensing structure. The first bow-shape compensation capacitor structure 64 and the second bow-shape compensation capacitor structure 62 are respectively arranged on the upper side and the down side of the three seismic mass sensing structure 71 (viewed from FIG. 9). In comparison with FIG. 6, the major axes of the first bow-shape compensation capacitor structure 64 and the second bow-shape compensation capacitor structure 62 in FIG. 9 are parallel to the X axis; the major axes of the first seismic mass 23c, the second seismic mass 23b and the third seismic mass 23a in FIG. 9 are parallel to the Y axis. In other words, the major axes of the compensation capacitor structures are vertical to the major axes of the seismic masses. Refer to FIG. 10. In the three seismic mass sensing structure 73 of FIG. 10, the major axes of the first seismic mass 23c, the second seismic mass 23b and the third seismic mass 23a are parallel to the Y axis; the major axes of the first bow-shape compensation capacitor structure 64 and the second bow-shape compensation capacitor structure 62 are respectively arranged beside the adjacent long side and short side of the three seismic mass sensing structure 73, wherein the major axis of the first bow-shape compensation capacitor structure 64 is parallel to the Y axis; the major axis of the second bow-shape compensation capacitor structure 62 is parallel to X axis. Therefore, the major axis of the second bow-shape compensation capacitor structure 62 is vertical to the major axes of the first seismic mass 23c, the second seismic mass 23b and the third seismic mass 23a. Refer to FIG. 11. Four bow-shape compensation capacitor structures are respectively arranged beside four sides of the three seismic mass sensing structure 75, wherein two first bow-shape compensation capacitor structures 64 are respectively arranged beside a pair of adjacent long side and short side; two second bow-shape compensation capacitor structures 62 are respectively arranged beside another pair of adjacent long side and short side. Refer to FIG. 12. Four bow-shape compensation capacitor structures are respectively arranged beside four corners of the three seismic mass sensing structure 77, wherein two first bow-shape compensation capacitor structures 64 are respectively arranged beside two corners of one short side; two second bow-shape compensation capacitor structures 62 are respectively arranged beside two corners of the other short side. Therefore, one or more compensation capacitor structures may be arranged beside the three seismic mass sensing structure of three seismic mass Z-axis accelerometer of the present invention to eliminate the influence of the stress-induced deformation.

FIG. 13 and FIG. 14 are front views schematically showing the bow-shape compensation capacitor structures of the MEMS substrate structure of a three seismic mass Z-axis accelerometer according to one embodiment of the present invention. In FIG. 13, the bow-shape compensation capacitor structure 82 is a back-to-back type arrangement and includes a forward compensation capacitor pair, wherein the first capacitor plate 86 is an arc-shape capacitor plate; the turning structure 85 which is connected with the first capacitor plate 86 has a shape of a straight line; the second capacitor plate 88 has a shape of a plain. In such a design, the arc-shape capacitor plate is used to magnify strain. In FIG. 14, the bow-shape compensation capacitor structure 84 is a back-to-back type arrangement one and includes a backward compensation capacitor pair, the first capacitor plate 86 is an arc-shape capacitor plate; the turning structure 85 which is connected with the first capacitor plate 86, has a shape of a straight line; the second capacitor plate 88 has a shape of a plain. Such a design also uses the arc-shape capacitor plate to magnify strain. Therefore, the stress sensitivity of the buckling structure of the buckling capacitor structure may be modified via adjusting the width and/or length of the buckling structure, the curvature of the turning angle of the buckling structure, or the initial distance of a pair of buckling structures. In the bow-shape compensation capacitor structure of the present invention, the stress-induced structural strain is magnified via modifying the geometrical design of the capacitor plates and/or the turning structures.

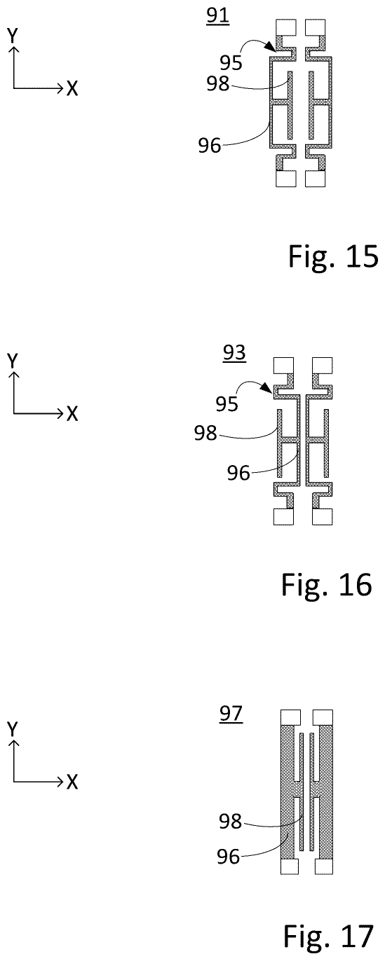

FIGS. 15-17 are front views schematically showing the non-compensation capacitor pair structures of the MEMS substrate structure of a three seismic mass Z-axis accelerometer according to one embodiment of the present invention. In some cases, the MEMS sensing structure may be equipped with non-sensitive dummy compensation structures. The dummy compensation structures are only used to form a symmetric equi-capacitance structure. For example, the width of the buckling structure is maximized to reduce buckling deformation. Alternatively, several turning structures are used to reduce the lateral deformation of buckling. In FIG. 15, the bow-shape compensation capacitor structure 91 is a back-to-back type arrangement, wherein both the first capacitor plate 96 and the second capacitor plate 98 have a plain shape; the turning structure 95 includes four right angles. In FIG. 16, the bow-shape compensation capacitor structure 93 is a face-to-face type arrangement, wherein both the first capacitor plate 96 and the second capacitor plate 98 have a plain shape; the turning structure 95 includes four right angle corners. In FIG. 17, the bow-shape compensation capacitor structure 97 is a back-to-back type arrangement, wherein both the first capacitor plate 96 and the second capacitor plate 98 have a plain shape; the bow-shape compensation capacitor structure 97 does not have any turning structure; the width of the first capacitor plate 96 is maximized.

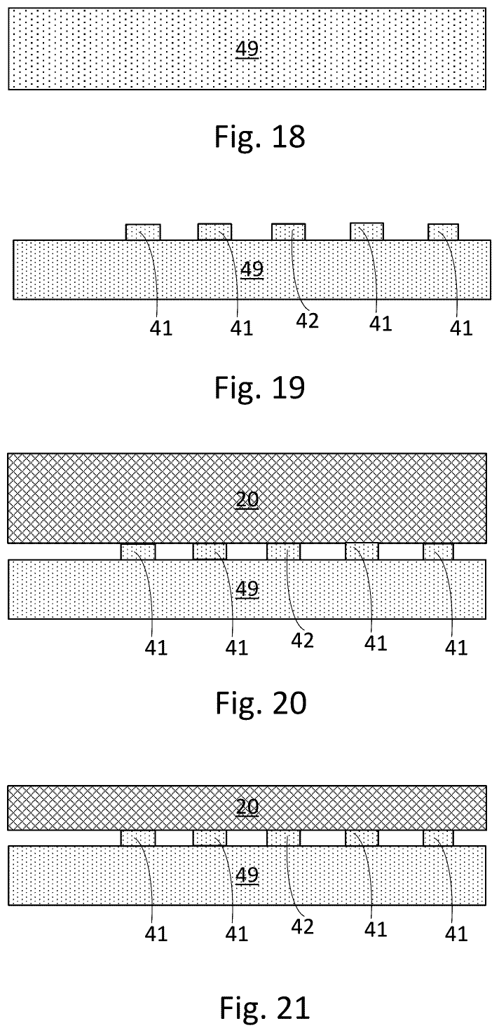

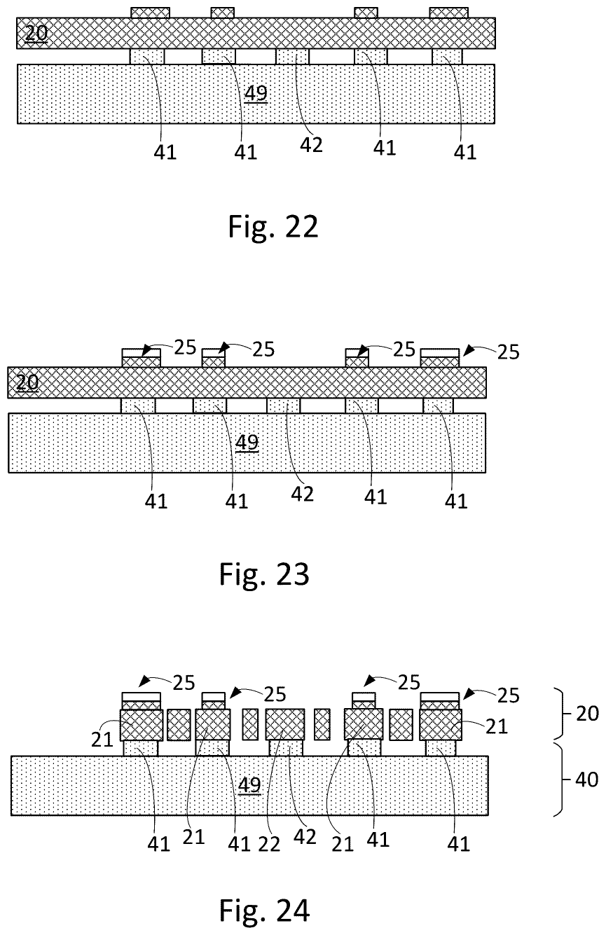

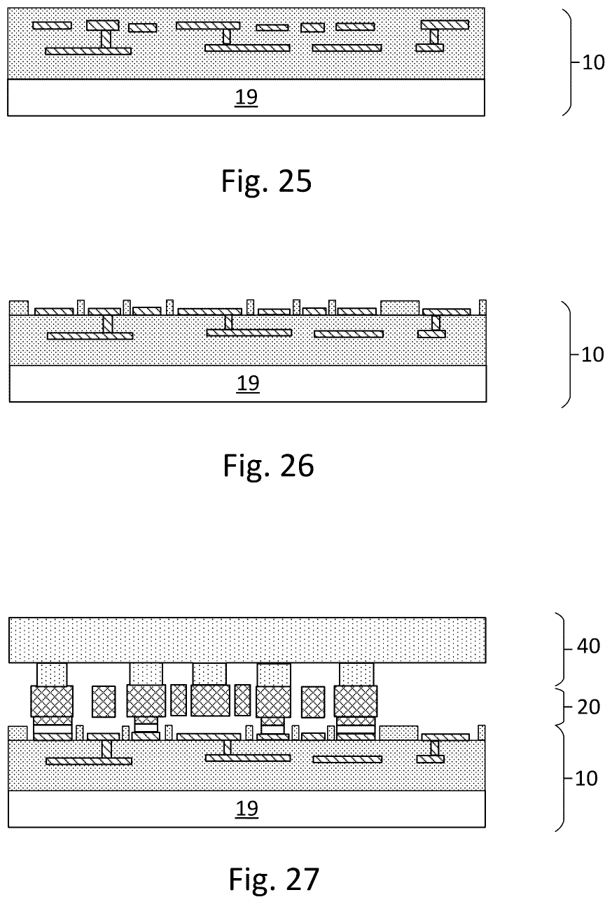

FIGS. 18-27 are sectional views schematically showing the manufacturing process of a three seismic mass Z-axis accelerometer according to one embodiment of the present invention. Refer to FIG. 1, FIG. 18 and FIG. 19. Firstly, provide a cap body 49, and use an ordinary patterning process, including photolithographic steps, exposure steps, developing steps and etching steps, to form first cap pillars 41 and second cap pillars 42 on the surface of the cap body 49, wherein the outermost first cap pillar 41 is an annular structure. Refer to FIG. 1, FIG. 20 and FIG. 21. Next, join a primitive MEMS substrate 20 to the patterned cap body 49 in an appropriate method, such as a fusion bonding method, and thin the primitive MEMS substrate 20. Refer to FIG. 1, FIG. 22, FIG. 23 and FIG. 24. Next, stacked layers are deposited and pattern the stacked layers on the thinned MEMS substrate 20 by appropriate methods to form a bonding structure 25 and then the elements of the MEMS sensing structure, including electric-connection anchor structures 21, cap anchor structures 22, seismic masses, connecting springs, and stop springs are formed. Refer to FIG. 1, FIG. 25, and FIG. 26. Next, a circuit layer above a COMS body 19 forms in a conventional method, and reveal electric-conduction pads, bonding pads, and electrode plates on the surface in appropriate etching methods. Refer to FIG. 1, FIG. 24, and FIG. 27. Next, flip the combination of the MEMS substrate and the cap substrate 40 on the CMOS substrate 10 and join them together in an appropriate method, such as a eutectic bonding method. If necessary, thin the cap substrate 40. Then, saw the cap substrate 40 and the MEMS substrate 20 to obtain the three seismic mass Z-axis accelerometer of the present invention.

The embodiments described above are to demonstrate the technical thought and characteristics of the present invention to enable the persons skilled in the art to understand, make, and use the present invention. However, these embodiments are only to exemplify the present invention but not to limit the scope of the present invention. Any equivalent modification or variation according to the spirit of the present invention is to be also included by the scope of the present invention.

What is claimed is:

1. A three seismic mass Z-axis accelerometer, comprising a complementary metal oxide semiconductor (CMOS) substrate, a micro electro mechanical system (MEMS) substrate and a cap substrate, which are arranged parallel to each another and bonded to each another, wherein the MEMS substrate includes:
two seesaw seismic masses;
a connection seismic mass, arranged between the two seesaw seismic masses and respectively connected with the two seesaw seismic masses through a plurality of connecting springs, and a perforated areas formed between the connection seismic mass and one of the two seesaw seismic masses, wherein the connection seismic mass and two seesaw seismic masses are respectively corresponding to a plurality of sensing electrode plates on the CMOS substrate to form a plurality of capacitor structures;
a plurality of electric-connection anchor structures, respectively fixed to and electrically connected with the CMOS substrate and the cap substrate, wherein each of the electric-connection anchor structures is corresponding to and fixed to a first cap pillar of the cap substrate and a bonding pad of the CMOS substrate; and
a plurality of cap anchor structures, respectively fixed to the cap substrate, wherein each of the cap anchor structures is corresponding to and fixed to a second cap pillar; the plurality of electric-connection anchor structures and the plurality of the cap anchor structures are arranged in the perforated areas.

2. The three seismic mass Z-axis accelerometer according to claim 1, wherein the plurality of cap anchor structures are connected with the seesaw seismic masses through a plurality of sensing springs and connected with the plurality of electric-connection anchor structures through a plurality of electric-connection springs; and the plurality of sensing springs and the plurality of electric-connection springs are arranged in the perforated areas.

3. The three seismic mass Z-axis accelerometer according to claim 1, wherein the MEMS substrate further includes a plurality of stop springs, which are connected with the plurality of cap anchor structures and arranged in the perforated areas.

4. The three seismic mass Z-axis accelerometer according to each of claim 1, wherein the MEMS substrate further includes a plurality of buckling compensation capacitor structures arranged in a perimeter of the connection seismic mass and the seesaw seismic masses.

5. The three seismic mass Z-axis accelerometer according to claim 4, wherein each of the buckling compensation capacitor structures includes two buckling structures arranged symmetrically; each of the buckling structures includes a first capacitor plate and a second capacitor plate; two ends of the first capacitor plate are respectively connected with fixing anchor structures through two buckling structures; the second capacitor is connected with a middle region of the first capacitor plate.

6. The three seismic mass Z-axis accelerometer according to claim 5, wherein any one of the first capacitor plates is an arc-shape plate or a plain plate.

7. The three seismic mass Z-axis accelerometer according to claim 5, wherein the two second capacitor plates are disposed between the two first capacitor plates, or the two first capacitor plates are disposed between the two second capacitor plates.

8. The three seismic mass Z-axis accelerometer according to each of claim 1, wherein the MEMS substrate further includes a plurality of bonding structures fixed to between the electric-connection anchor structure and the bonding pad to cooperate with the first cap pillars around the cap substrate itself to form an airtight annular structure.

9. A method for manufacturing the three seismic mass Z-axis accelerometer according to each of claim 1, comprising steps:
providing the cap substrate having the plurality of first cap pillars and the plurality of second cap pillars;
joining a primitive substrate to the cap substrate in a fusion method;
patterning the primitive substrate to form the micro electro mechanical system (MEMS) substrate;
providing the complementary metal oxide semiconductor (CMOS) substrate having the plurality of bonding pads and the plurality of electrode plates; and
joining the MEMS substrate to the CMOS substrate in a eutectic method.

10. A method for manufacturing the three seismic mass Z-axis accelerometer according to each of claim 4, comprising steps:
providing the cap substrate having the plurality of first cap pillars and the plurality of second cap pillars;
joining a primitive substrate to the cap substrate in a fusion method;
patterning the primitive substrate to form the micro electro mechanical system (MEMS) substrate;
providing the complementary metal oxide semiconductor (CMOS) substrate having the plurality of bonding pads and the plurality of electrode plates; and
joining the MEMS substrate to the CMOS substrate in a eutectic method.
